(19) United States
(12) Patent Application Publication
(10) Pub. No.: US 2010/0142154 A1
(43) Pub. Date: Jun. 10, 2010

(54) Thermally Dissipative Enclosure Having Shock Absorbing Properties

(75) Inventors: Roeland Collet, Olympia, WA (US); Selso Luanava, Woodinville, WA (US); Thomas Byeman, Bothell, WA (US); Joel E. Hegland, Snohomish, WA (US); Randall J. Whalen, Woodinville, WA (US)

Correspondence Address: MICROVISION, INC., 6222 185TH AVENUE NE, REDMOND, WA, 98052, US

(73) Assignee: Microvision, Inc., Redmond, WA (US)

(21) Appl. No.: 12/328,478

(22) Filed: Dec. 4, 2008

(51) Int. Cl. H05K 7/20; G03B 21/16

(52) U.S. Cl. 361/714; 353/52

(57) ABSTRACT

A thermally dissipative housing (200) includes a rigid housing (203) and a compliant heat spreader (215). The compliant heat spreader (215) is thermally coupled to a heat-generating component (201) disposed within the thermally dissipative housing (200). The compliant heat spreader (215) removes heat from the heat-generating component (201) and transfers it along an interior surface of the rigid housing (203) by passing along an interior (209) of the rigid housing (203) across at least a portion of the interior surface area (211) of the rigid housing (203). The compliant heat spreader (215) transfers heat to the surface of the rigid housing (203) without substantially interfering with the shock absorbing properties of the rigid housing (203).

### BACKGROUND

1. Technical Field

This invention relates generally to housings for electrical systems having heat generating components and more particularly to a housing system for handheld devices that facilitates heat dissipation through the housing to the external environment while providing shock absorbing properties to sensitive components disposed within the housings.

2. Background Art

The manufacturing and design technology for electronic devices has advanced significantly in recent years. Modern electronic devices are often portable and offer increased functionality and performance in smaller packages. For instance, in the field of image projection systems, image projectors were once large, bulky, noisy devices that required a sturdy table upon which to rest while in operation. Today, advances in technology provide projection systems that are easily portable and that can be connected to a portable computer or handheld device.

In short, today's devices “accomplish more in less space.” Portable computers, mobile data devices, gaming devices, and multimedia players are incorporating more processing power, more functionality, and more components into smaller mechanical form factors. One issue associated with this trend towards miniaturization is that of heat dissipation. Electronic components must be kept cool to function properly. When these components overheat, their reliability can be compromised. One technique used for cooling compact electronic devices is dissipating heat into the surrounding environment.

In many systems, designers must focus additional thermal management attention on a few specific components. For instance, power supplies, microprocessors, and optical components such as image projection devices tend to produce large amounts of heat. Consequently, they are more difficult to keep cool. Further compounding the issue is the fact that these components are often more sensitive to temperature changes. As a result, improper thermal management can compromise their performance.

Turning now to FIG. 1, illustrated therein is one prior art thermal management system 100. A heat generating electronic component 101, such as a microprocessor, optical transceiver, or power converter, is mounted on a chassis 102 within a housing 103. The housing 103 is generally manufactured from a thermally conductive material, such as metal. The chassis 102 is bolted to the housing 103, perhaps by using rivets 104. The housing 103 includes airflow perforations 105 that allow ambient air to pass through the housing 103 as a result of convection currents within the housing 103.

Thermal heat sinks 106,107, which are generally manufactured from a rigid material such as an aluminum alloy, are mounted directly to the heat generating electronic component 101. These heat sinks 106,107 generally include a set of fins 108 that extend outwardly from the heat sink 107 so as to increase the overall surface area of the heat sink 107. In some devices, the fins 108 protrude through the airflow perforations 105 in an attempt to deliver more of the heat to the air outside the housing 103.

The problem with these rigid heat sinks 106,107 is four-fold: First, to be effective the surface of heat generating electronic component 101 coupling to the rigid heat sinks 106,107, as well as the heat sinks 106,107 themselves, must have a relatively large surface area. In today's compact electronics, this is seldom the case. Second, in addition to increasing the overall cost of the system 100, the attachment of heat sinks 106,107 to the heat generating electronic component 101 effectively increases the mass of that electronic component. When the system 100 is subjected to mechanical shock, such as in the drop testing commonly required for certification of consumer electronics, the reliability of sensitive devices like optical projection components can be compromised due to the excessive forces being applied to those components when the system collides with a hard surface.

Third, heat sink mounting systems can be unreliable due to the difficulties associated with mechanical adhesion systems. Further, the bulk and weight of most heat sinks can make coupling even more difficult. When adhesives and clips are used to mount heat sinks to components, the attachment may not be stable or reliable. Further, it may impair the operation of components like optical projection elements.

Fourth, heat sinks take up large amounts of room within the housing. Consumers today are demanding smaller and smaller electronics. There is often simply not enough real estate within a device to include bulky, metal heat sinks.

Note that in some other prior art systems, in an attempt to reduce the size of heat sinks that are required, fans are added within the housing to improve airflow. Such fans, working in conjunction with the airflow perforations, attempt to move heat from the interior of the housing to the exterior of the device by forcing air through the airflow perforations. The problems associated with fans are reliability, size, and power consumption. When a fan fails, it is easy for a device to quickly overheat. Second, fans use relatively large amounts of energy. In a portable electronic device that operates with a battery as an energy source, the inclusion of a fan means a much shorter run time on a single charge cycle. Additionally, fans are large devices that often require larger housings to accommodate them.

There is thus a need for an improved system for dissipating heat to the surrounding environment without the need for a fan or air-flow perforations, and that offers sufficient shock absorption so as not to impair component operation when the system is dropped.

### BRIEF DESCRIPTION OF THE DRAWINGS

FIG. 1 illustrates a prior art thermal management system.

FIG. 2 illustrates a sectional view of one thermal management system in accordance with embodiments of the invention.

FIG. 3 illustrates a sectional view of another thermal management system in accordance with embodiments of the invention.

FIG. 4 illustrates a sectional view of another thermal management system in accordance with embodiments of the invention.

FIG. 5 illustrates a sectional view of another thermal management system in accordance with embodiments of the invention.

FIG. 6 illustrates a sectional view of another thermal management system in accordance with embodiments of the invention.

FIG. 7 illustrates an exploded view of one thermal management system in accordance with embodiments of the invention.

FIGS. 8 and 9 illustrate assembled views of one thermal management system in accordance with embodiments of the invention.

FIG. 10 illustrates a plot of temperature change between an ambient environment and the interior of a housing having a heat generating electronic component disposed therein versus thermal conductivity of a one-millimeter thick housing in accordance with embodiments of the invention.

FIG. 11 illustrates one image projection device suitable for use with embodiments of the invention.

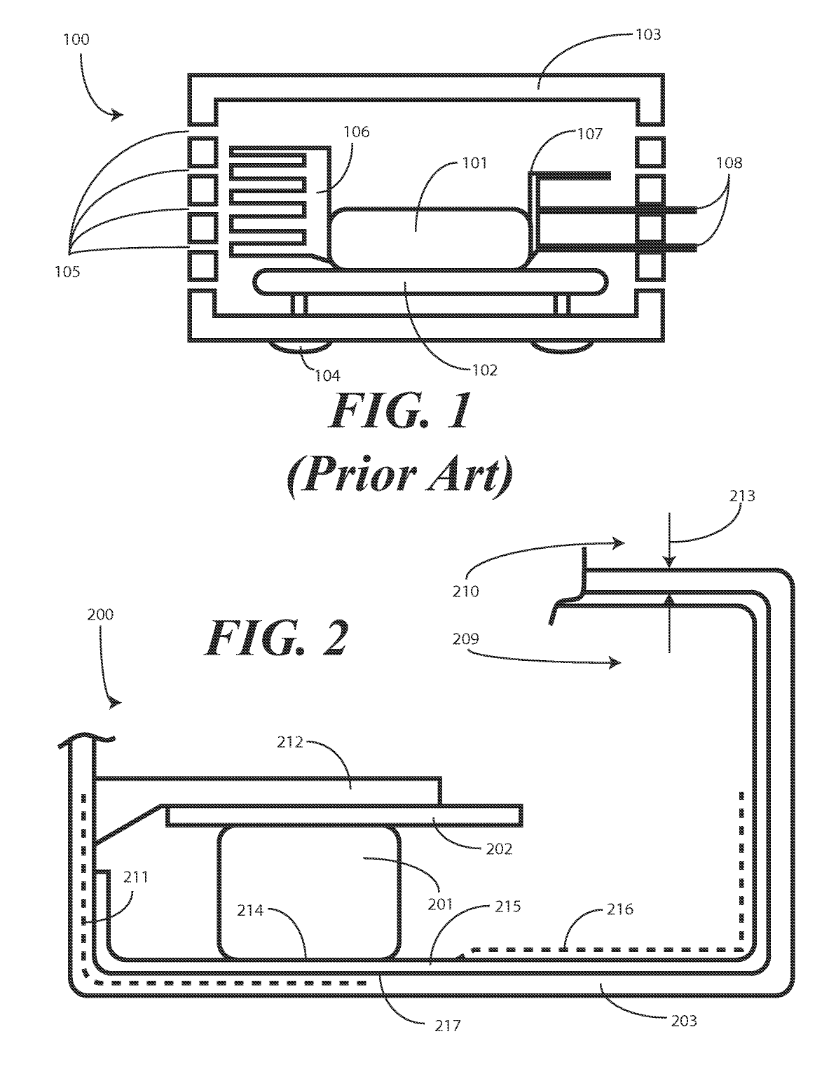

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE INVENTION

Before describing in detail embodiments that are in accordance with the present invention, it should be observed the apparatus components have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein. It is expected that one of ordinary skill, notwithstanding possibly significant effort and many design choices motivated by, for example, available time, current technology, and economic considerations, when guided by the concepts and principles disclosed herein will be readily capable of generating such apparatus components with minimal experimentation.

Embodiments of the invention are now described in detail. Referring to the drawings, like numbers indicate like parts throughout the views. As used in the description herein and throughout the claims, the following terms take the meanings explicitly associated herein, unless the context clearly dictates otherwise: the meaning of “a,” “an,” and “the” includes plural reference, the meaning of “in” includes “in” and “on.” Relational terms such as first and second, top and bottom, and the like may be used solely to distinguish one entity or action from another entity or action without necessarily requiring or implying any actual such relationship or order between such entities or actions. Also, reference designators shown herein in parenthesis indicate components shown in a figure other than the one in discussion. For example, talking about a device (10) while discussing figure A would refer to an element, 10, shown in figure other than figure A.

Passively cooling, i.e., cooling without a fan, forced liquid, or other powered cooling device, small form factor, high-power electronics provides a significant design challenge. For example, many consumer electronics devices have strict requirements regarding “touch temperature.” A particular device may be required to be able to operate continually in a warm environment with the surface temperature of the device never exceeding a predetermined limit, such as 50 or 60 degrees centigrade, even though the components may be operating at 60 or 65 degrees centigrade within the device. For example, some standards set forth momentary contact temperature exposure limits with which devices must comply. Exemplary standards include MIL-STD-1472F and IEC 60950-1. These standards also set forth continuous contact temperature exposure limits in some cases. In optical devices, such as laser-based projection systems, the design constraints can be especially daunting given the limited types of available enclosure materials.

By way of example, metal enclosures—while working well to transfer heat from the interior of the enclosure to the outer environment—generally become too hot to handle at relativelty low surface temperatures limiting the delta temperature with the ambient and therefore the total heat transfer Plastic enclosures tend to stay cooler to the touch due to their relatively lower thermal conductivity. However, they can tend to have “hot spots” and also tend not to effectively deliver heat from the components through enclosure to the environment.

To remedy these issues, embodiments of the present invention employ a hybrid housing that includes a rigid housing material, such as a thermoplastic, used in conjunction with a compliant thermally conductive heat spreader that passes along an interior of the housing. In addition to spreading heat across the surface of the enclosure, the compliant heat spreader also permits the rigid housing to retain its shock absorbing properties. In other words, the heat spreader is chosen to be compliant so that it will not interfere with the shock absorbing properties of the housing. Rather than using a rigid heat spreader—such as a piece of metal—within the device that would cause the rigidity of the overall housing to increase, embodiments of the present invention use a compliant material such as graphite to permit the thermoplastic housing to still absorb shock when the system is dropped. As such, sensitive electronics disposed within the housing are not subject to increased forces during drop due to the incorporation of the internal heat spreader. Further, enclosures in accordance with embodiments of the present invention provide comfortable touch temperatures, along with comparable heat removal properties exhibited by metal enclosures, while being easy and inexpensive to manufacture.

Embodiments of the present invention include a rigid housing manufactured from a shock absorbing, high emissivity, low-thermally conductive material such as thermoplastic along with a compliant, thermally conductive heat spreader disposed along an interior of the housing. The overall system facilitates heat transfer via radiation, convection and conduction from components within the system to the external environment, while still providing greater shock absorbing properties than prior art thermal management systems.

The compliant thermally conductive material, which in one embodiment is a die-cut, graphite sheet having a thickness of between 100 um and 500 um, acts as a heat spreader. The heat spreader provides a thermally conductive component that spreads heat along an interior surface area of the housing so as to make the enclosure appear to be effectively isothermal. In one embodiment, for instance, the heat spreader passes across at least fifty percent of the interior surface area of the housing. Embodiments of the invention constructed in this fashion deliver emissivitiy of between 0.6. and 1.0. Experimental testing has shown that an enclosure emissivity of 0.8 works well with embodiments of the invention.

The housing material, which in one embodiment is a polycarbonate-ABS plastic blend, provides a more comfortable touch temperature for the user. Further, when using a thermoplastic as the housing material, the touch temperature can be higher—while still being comfortable—than it can with other materials. For instance, while testing has shown that metal housings are comfortable only to forty degrees centigrade, plastic housings can still “feel” comfortable at sixty degrees centigrade when using thermoplastic housings with a heat spreader disposed beneath. Additionally, the housing material absorbs mechanical energy when the overall device is dropped, thereby insulating components within the housing from excessive drop forces.

The high-emissivity, low-thermally conductive housing material also allows the overall enclosure to deliver heat to the environment by radiation in addition to convection and conduction. Radiant heat transfer significantly improves the overall thermal performance of the system, in that it can account for nearly half the total heat dissipation in certain applications.

Turning now to FIG. 2, illustrated therein is one embodiment of a thermally dissipative housing 200 for heat generating electronic components, e.g. heat-generating component 201, in accordance with embodiments of the invention. The thermally dissipative housings 200 of the present invention are suitable for a wide range of applications, including power supplies, imaging devices, and microprocessor applications. Embodiments of the present invention are well suited for optical applications, such as for providing compact, thermally efficient portable projection systems, including laser-based projectors.

A rigid housing 203, shown in FIG. 2 in a cut-away sectional view, has an interior 209 and an exterior 210. The interior 209 of the rigid housing 203 includes an interior surface area 211 represented by the dashed line in FIG. 2. The term “rigid” is used to indicate that the rigid housing 203 is not generally flexible or compliant. However, in one embodiment the rigid housing 203 is manufactured from a thermoplastic such as polycarbonate, ABS, or a polycarbonate-ABS blend. As such, the material is somewhat deformable and can withstand moderate amounts of shock by absorbing impact forces. Thus, it need not be perfectly rigid, but is rigid in the sense that any deformation is quickly restored so that the housing retains its overall shape.

Thermoplastics, in one embodiment, are chosen as materials for the rigid housing 203 for a variety of reasons. First, they are relatively inexpensive and easy to manufacture. Plastic housing members can be manufactured, for instance, by injection molding. Second, plastic housings are relatively impervious to shock. For instance, when they are dropped from a height of four or five feet to tile, wood, carpet, or concrete—as is sometimes required during consumer product drop testing—they generally withstand the fall without breaking. Third, plastic housings have good energy absorption benefits for components disposed within the housing. When dropped, the housing will absorb substantial portions of the energy delivered at impact, thereby insulating components disposed within the plastic housing from some of these forces. One other reason for selecting thermoplastics is that they can be easily molded into complex, thin-walled, organic shapes.

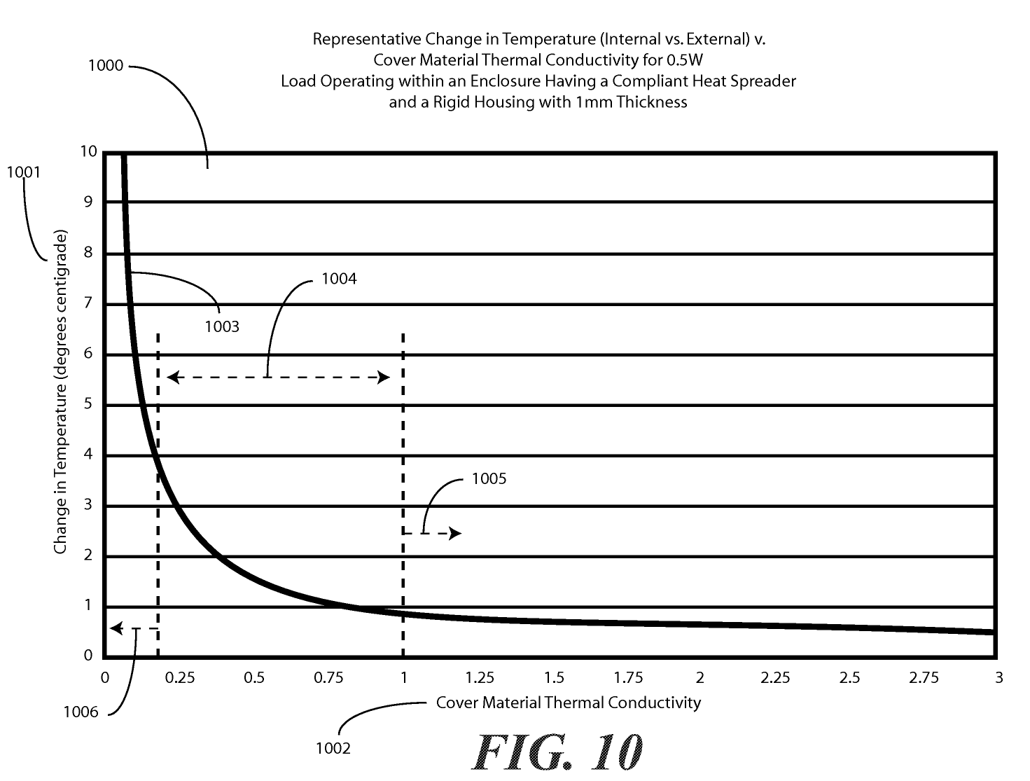

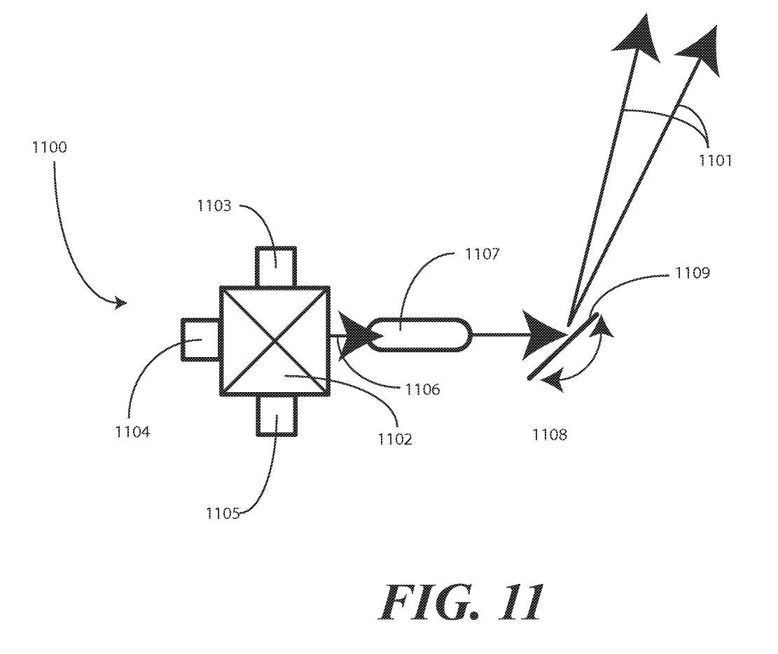

Another reason thermoplastic materials, such as a polycarbonate-ABS blend, are used with some embodiments of the invention is the thermal conductivity that can be achieved and designed into the material. Turning briefly to FIG. 10, illustrated therein is a plot 1000 of the change in temperature 1001 between the interior (209) of a thermoplastic rigid housing (203) having dimensions of roughly 120 mm×60 mm×15 mm with a 0.5 Watt load operating therein and its exterior (210) versus the thermal conductivity 1002 of the thermoplastic material. As the thermal conductivity 1002 decreases 1006, less heat gets delivered from the interior (209) to the exterior (210). Consequently, the change in temperature between the interior (209) and the exterior (210) increases. Conversely, as thermal conductivity 1002 increases 1005, more heat gets delivered from the interior (209) to the exterior (210). Thus, the change in temperature decreases between the interior (209) and the exterior (210). However, the surface temperature of the rigid housing (203) feels hotter. The acceptable touch temperature of the surface of the device increases as the thermal conductivity 1002 increases. Embodiments of the present invention employ a range of thermal conductivity where the change in temperature is relatively low and the touch temperature is elevated, but still acceptable for a user to touch.

The thermoplastic material can be designed to have any of a range of thermal conductivities. Embodiments of the present invention with laser projection systems have shown that rigid housings (203) having a thermal conductivity with a range 1004 of between 0.1 Watts/meter*Kelvin and 1.0 Watts/meter*Kelvin work well in that they deliver sufficient amounts of thermal energy to the exterior environment when employed with a compliant heat spreader without causing the surface temperature to become too hot. Said differently, this range minimizes the change in temperature between the interior (209) and the exterior (210) while maintaining an acceptable touch temperature of the exterior (210). Specifically, a 118 mm×61 mm×14 mm housing with a battery operated MEMS scanning mirror projector running therein can be kept below 55 degrees centigrade easily. Polycarbonate-ABS blends for some embodiments of the invention are therefore constructed to have thermal conductivities within this range 1004. Further, in accordance with some embodiments of the invention, the thickness (213) of the housing is selected to be between one and two millimeters. While thermoplastic materials are one type of material suitable for use as the rigid housing (203), it will be obvious to those of ordinary skill in the art having the benefit of this disclosure that other materials, including rubber-based materials, resin-based materials, and so forth, having similar shock absorbing properties and thermal conductivities, can also be used.

Turning now back to FIG. 2, a substrate, illustrated as a printed circuit board 202 in FIG. 2, is disposed within the rigid housing 203. In one embodiment, the printed circuit board 202 is configured in a fixed relationship with the rigid housing 203. For instance, as will be shown in later figures, the printed circuit board 202 can be coupled directly to the rigid housing 203. However, to improve the thermal management properties of the overall system, in the embodiment of FIG. 2 the printed circuit board 202 is coupled to a mechanical support 212 extending from the rigid housing 203.

One or more of the heat-generating components 201 are disposed along the printed circuit board 202. Heat generating components can include microprocessors, power generation components, or optical components such as projectors and image producing devices. In one embodiment, the heat-generating component 201 is an image projection device, such as a Microelectromechanical System (MEMS) image production device including laser light sources and a MEMS scanning mirror as an image modulation device.

Turning briefly to FIG. 11, illustrated therein is one embodiment of a block diagram of a display engine 1100 suitable for use with embodiments of the present invention. In one embodiment, the display engine 1100 comprises a scanned beam display engine configured to provide an adjustable or variable accommodation scanned beam 1101 for projection. A beam combiner 1102 combines the output of light sources 1103, 1104, 1105 to produce a combined modulated beam 1 106. A variable collimation or variable focusing optical element 1107 produces a collimated beam 1108 that is scanned by the scanning mirror 1109 as variably shaped scanned beam, which can be used for projection onto a surface.

In one embodiment, the display engine 1100 comprises a MEMS display engine that employs a MEMS scanning mirror to deliver light from the plurality of light sources 1103, 1104, 1105. MEMS scanning display engines suitable for use with embodiments of the present invention are set forth in US Pub. Pat. Appln. No. 2007/0159673, entitled, “Substrate-guided Display with Improved Image Quality”; which is incorporated by reference herein.

Turning now back to FIG. 2, a compliant heat spreader 215 is thermally coupled 214 to the heat-generating component 201. The compliant heat spreader 215 passes along the interior 209 of the rigid housing 203 across a portion of the interior surface area 211. In one embodiment, the compliant heat spreader 215 passes along at least twenty-five percent of the interior surface area 211. In another embodiment, the compliant heat spreader 215 passes along at least fifty percent of the interior surface area 211.

The amount of interior surface area 211 covered by the compliant heat spreader 215 will vary with application. For instance, it will depend upon the number of heat-generating components 201, the permissible operating temperatures, and power consumption. Additionally, it will depend upon the surface touch temperature that can be tolerated, as well as the overall dimensions of the device. In one embodiment, for example, the rigid housing 203 has dimensions of less than 200×100×20 millimeters. However, a battery and battery door must be accommodated within this small space. Where the heat-generating component 201 comprises a MEMS display engine, experimental testing has shown that a rigid housing 203 manufactured from a polycarbonate-ABS blend, with thermal conductivity of between 0.2 Watts/meter*Kelvin and 1.0 Watts/meter*Kelvin and a thickness of about 1 millimeter, with a compliant heat spreader 215 covering about fifty percent of the internal surface area 211, is sufficient to avoid hot spots, keep the surface temperature below 45 degrees centigrade, and to make the overall enclosure approach being effectively isothermal. This can even be accomplished with no metal exposed from the rigid housing 203 and without airflow perforations in the rigid housing.

The materials that can be used for construction of the compliant heat spreader 215 includes flexible copper sheets such as copper foil, flexible aluminum sheets such as aluminum foil, and flexible graphite sheets. To avoid shorting electrical components, the compliant heat spreader can be encapsulated in an optional electrically insulating material 216, such as Polyethylene terephthalate (PET). In one embodiment, the compliant heat spreader 215 is a flexible graphite fiber sheet having a thickness of between 100 um and 500 um. Such material is generally inexpensive, easily die cut, and easy to work with in a manufacturing environment. Further, such a material does not sufficiently interfere with the shock absorbing properties of the rigid housing 203. For instance, where the heat-generating component 201 is a sensitive component, such as an image projection system, the combination of the polycarbonate-ABS rigid housing 203 and the compliant heat spreader 215 manufactured from graphite fiber will absorb enough energy that the image projection system will be subjected to a shock force of less than 3000 times the earth's gravitational force, “3000 G,” when dropped from four feet to concrete.

The compliant heat spreader 215 is, in one embodiment, thermally coupled 217 to the rigid housing 203. This can be achieved in several ways. In one embodiment, the compliant heat spreader 215 is adhesively affixed to the rigid housing 203. In another embodiment, the compliant heat spreader 215 is thermally coupled 217 to the rigid housing 203 by an insert molding process. Specifically, the compliant heat spreader 215 can be inserted into an injection-molding tool. The thermoplastic material of the rigid housing 203 can then be injected about the compliant heat spreader 215 such that the compliant heat spreader 215 becomes an integral part of the rigid housing 203. Insert molding allows the parts to be formed in complex three-dimensional shapes. Other advantages of the insert molded embodiment are that integrating the compliant heat spreader 215 into the housing facilitates thinner thermoplastic layers, easier manufacture through part count reduction, increased surface area coverage, and being able to uniquely design the thickness of the thermoplastic layers about the heat spreader layers.

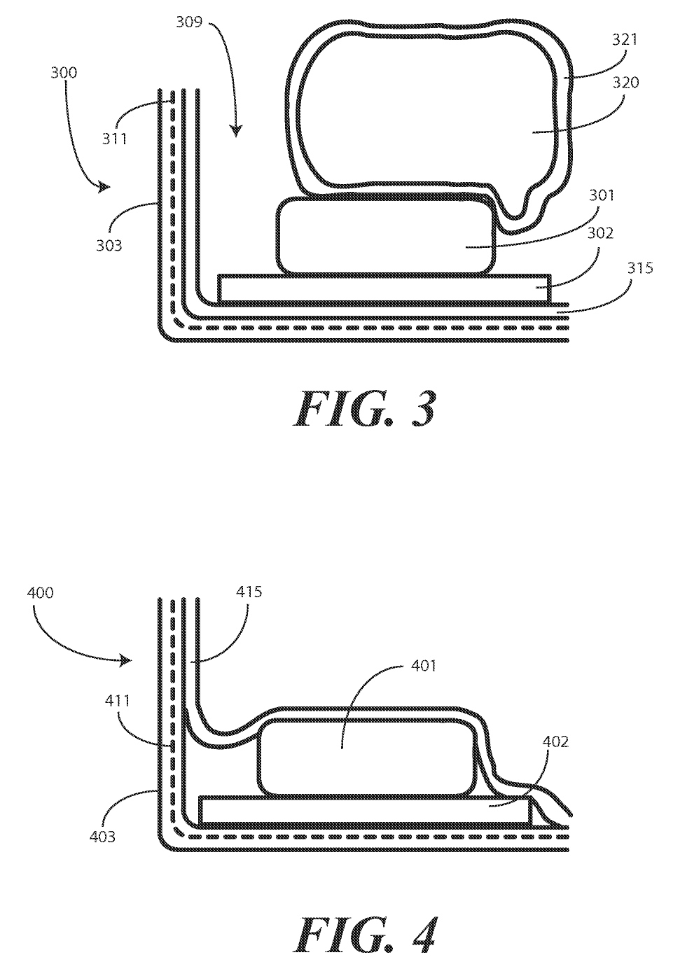

Turning now to FIG. 3, illustrated therein is an alternate embodiment of a thermally dissipative housing 300 in accordance with the invention. In FIG. 3, the heat-generating component 301 is disposed along a substrate, illustrated in FIG. 3 as a printed circuit board 302. The compliant heat spreader 315 is disposed between the substrate and the rigid housing 303. Heat is delivered to the compliant heat spreader 315 through the substrate. The compliant heat spreader 315 then spreads the heat along the interior surface area 311 of the rigid housing 303 for dissipation to the outside environment.

To further distribute the heat, embodiments of the invention may employ an optional thermal management feature. Specifically, a compressible non-electrically conductive material 320—such as compressible foam—may be added to the interior 309 of the rigid housing. A loop 321 of thermally conductive material—such as graphite—can then be disposed about the compressible non-electrically conductive material 320. This thermal management feature can then be compressed between portions of the rigid housing 303 and the heat-generating component 301 so as to transfer heat from the heat-generating component 301 to the interior surface of the rigid housing 303. While this optional thermal management feature is shown only in FIG. 3, it will be clear to those of ordinary skill in the art having the benefit of this disclosure that the invention is not so limited. Any of the various embodiments may employ this thermal management feature.

Turning now to FIG. 4, illustrated therein is an alternate embodiment of a thermally dissipative housing 400 in accordance with the invention. In FIG. 4, the heat-generating component 401 is disposed along a printed circuit board 402 substrate. The compliant heat spreader 415 passes along an interior surface area 411 of the rigid housing 403, and then passes atop the heat-generating component 401 so as to be thermally coupled to the heat-generating component 401. Heat is thus delivered to the compliant heat spreader 415 from the heat-generating component 401. The compliant heat spreader 415 then spreads the heat along the interior surface area 411 of the rigid housing 403 for dissipation to the outside environment. In one embodiment, the compliant heat spreader 415 passes across at least fifty percent of the interior surface area 411 of the rigid housing 403.

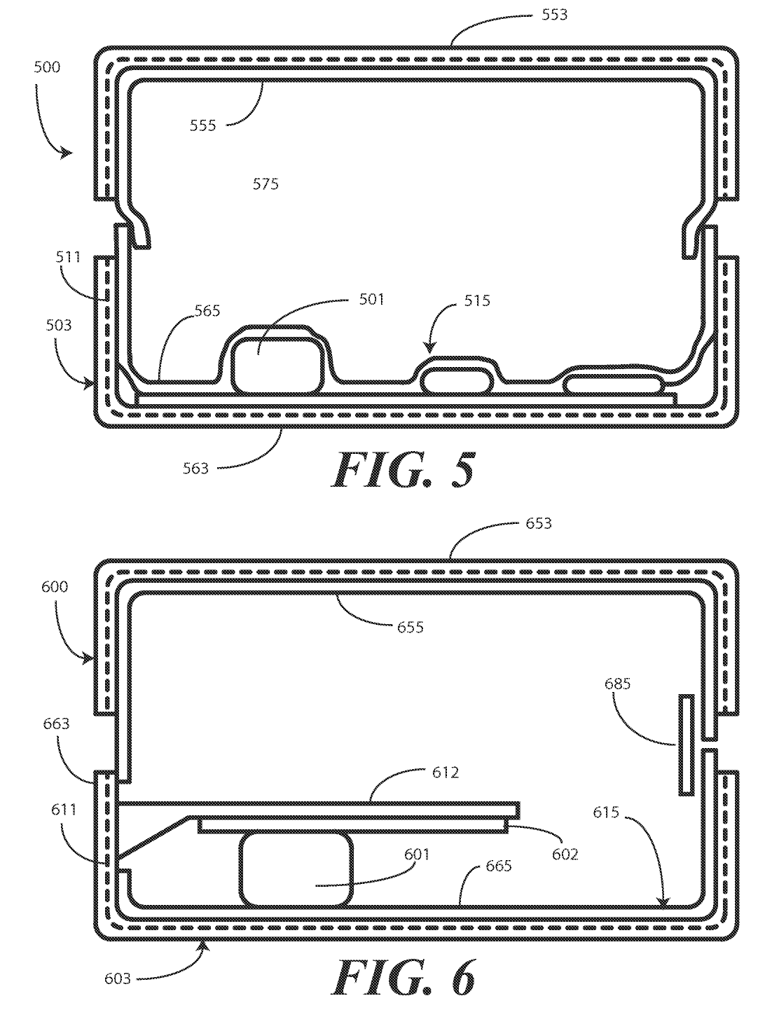

Turning now to FIG. 5, illustrated therein is an alternate embodiment of a thermally dissipative housing 500 in accordance with the invention. In FIG. 5, as in FIG. 4, the heat-generating component 501 is disposed upon a printed circuit board 502 substrate. The compliant heat spreader 515 passes along an interior surface area 511 of the rigid housing 503, and then passes atop the heat-generating component 501 for thermal coupling thereto. Heat is thus delivered to the compliant heat spreader 515 from the heat-generating component 501. Note that compressible foam can be placed atop the compliant heat spreader 515 to enhance the thermal coupling between the heat generating component 501 and the compliant heat spreader 515. The compliant heat spreader 515 then spreads the heat along the interior surface area 511 of the rigid housing 503 for dissipation to the outside environment.

In the embodiment of FIG. 5, the rigid housing 503 comprises two parts—a lower rigid housing 563, and an upper rigid housing 553. Additionally, the compliant heat spreader 515 comprises two parts—a lower compliant heat spreader 565, and an upper compliant heat spreader 555. Dividing the components into a plurality of pieces aids in ease of manufacture, as the interior components maybe set in place prior to sealing the outer enclosure.

The lower rigid housing 563 and upper rigid housing 553 can be coupled and sealed together in a variety of ways, including adhesives, sonic welding, or other means. Similarly, the lower compliant heat spreader 565 and upper compliant heat spreader 555 may be thermally and mechanically coupled together by adhesives or mechanical bonding. The lower compliant heat spreader 565 and upper compliant heat spreader 555 are thermally coupled together such that heat can be delivered from the lower compliant heat spreader 565 to the upper compliant heat spreader 555 for more optimal dissipation to the environment. In one embodiment, the lower compliant heat spreader 565 and upper compliant heat spreader 555 overlap each other at their interface 575 and affix to each other such that at least a portion of one of the compliant heat spreader members overlaps and is affixed to at least a portion of another compliant heat spreader member.

Turning now to FIG. 6, illustrated therein is an alternate embodiment of a thermally dissipative housing 600 in accordance with the invention. In FIG. 6, as in FIG. 2, the heat-generating component 601 is disposed upon a printed circuit board 602 substrate that is coupled to a mechanical support 612 extending from the rigid housing 603. The compliant heat spreader 615 passes along an interior surface area 611 of the rigid housing 603, and then passes beneath the heat-generating component 601 for thermal coupling thereto. Heat is thus delivered to the compliant heat spreader 615 from the heat-generating component 601. The compliant heat spreader 515 then spreads the heat along the interior surface area 611 of the rigid housing 603 for dissipation to the outside environment.

The rigid housing 603 comprises two parts—a lower rigid housing 663, and an upper rigid housing 653. To further spread the captured heat, in the embodiment of FIG. 6, the compliant heat spreader 615 comprises three parts—a lower compliant heat spreader 665, an upper compliant heat spreader 655, and an edge compliant heat spreader 685 for thermally coupling the compliant heat spreader components overlap and couple together such that heat can be delivered from one compliant heat spreader component to the next. In one embodiment, the compliant heat spreader components each other and affix to each other such that at least a portion of one of the compliant heat spreader members overlaps and is affixed to at least a portion of another compliant heat spreader member.

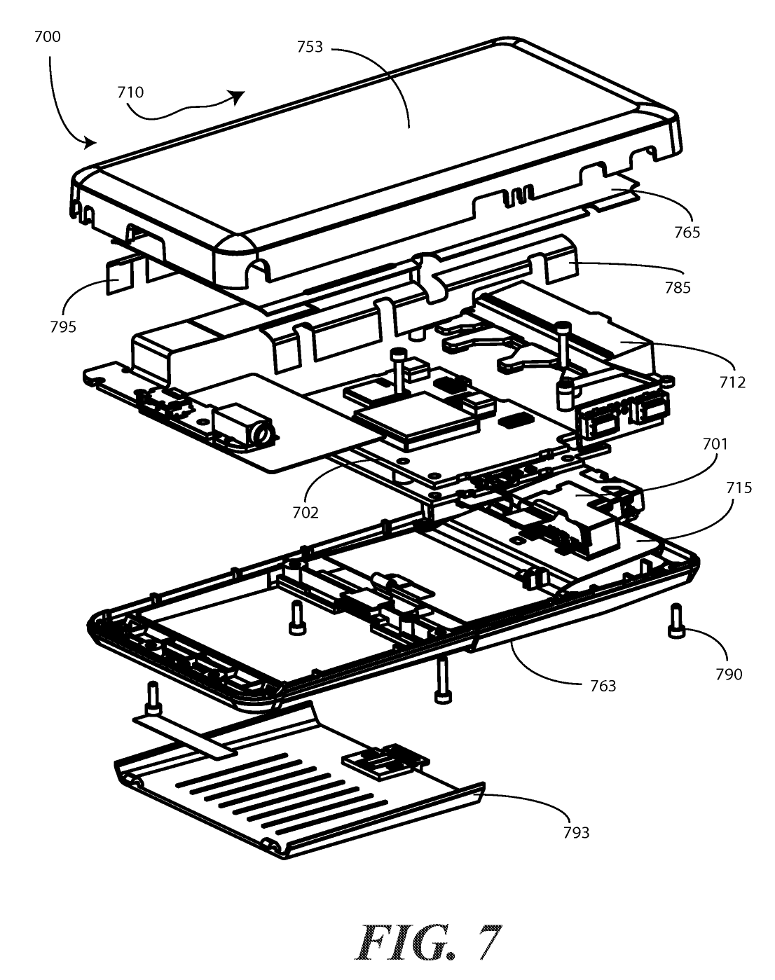

Turning now to FIG. 7, illustrated therein is one embodiment of an image production device 700 in accordance with embodiments of the invention. A projector 701, such as a MEMS scanning display engine, is mounted directly against the housing, perhaps by way of a compressible adhesive. Corresponding circuitry is mounted on a substrate 702. A compliant thermally conductive material 715 is thermally coupled to the projector 701.

A housing 703 is formed from an upper housing 753 and a lower housing 763. The upper housing 753 and lower housing 763 can be sealed together by adhesives, sonic welding, or by mechanical components, such as the screws 790 shown in FIG. 7. In one embodiment, the housing 703 includes no airflow perforations. Similarly, there is no exposed metal—such as heat sink fins or other heat removal devices—that is exposed along an exterior 710 of the housing. The dimensions of the illustrative housing 703 of FIG. 7 are less than 200×100×20 millimeters.

In one embodiment, the housing has a rigidity that is greater than that of the compliant thermally conductive material 715 and a thermal conductivity that is less than that of the compliant thermally conductive material 715. In one embodiment, the housing 703 is manufactured from a polycarbonate-ABS blend, while the compliant thermally conductive material is a flexible graphite material.

The projector 701 is powered by a rechargeable battery (not shown) that is replaceable through a battery door 793. Electronics used in projecting images are disposed along the various circuit boards within the device. The substrate 702 is fixed relative to the housing 703 by a mechanical support 712. The compliant thermally conductive material 715 is coupled, for example, to the lower housing 763 by a conductive adhesive film, which may be thermally conductive as well as mechanically adhesive.

The compliant thermally conductive material 715 couples to other heat spreaders 765,785,795 so as to pass along an interior of the housing 703 across a substantial portion of the interior of the housing 703. In the illustrative embodiment of FIG. 7, the compliant thermally conductive material passes along at least fifty percent of the interior of the housing 703 by way of the other heat spreaders 765,785,795.

In one embodiment, the compliant thermally conductive material 715 couples to the other heat spreaders 765,785,795 by a thermally conductive adhesive. For instance, the compliant thermally conductive material 715 overlaps and affixes to the side heat spreaders 785,795. Similarly, the side heat spreaders 785,795 overlap and affix to the upper heat spreader 765. As such, heat generated by the projector 701 is delivered about the interior of the device, through the housing 703, and to the exterior environment.

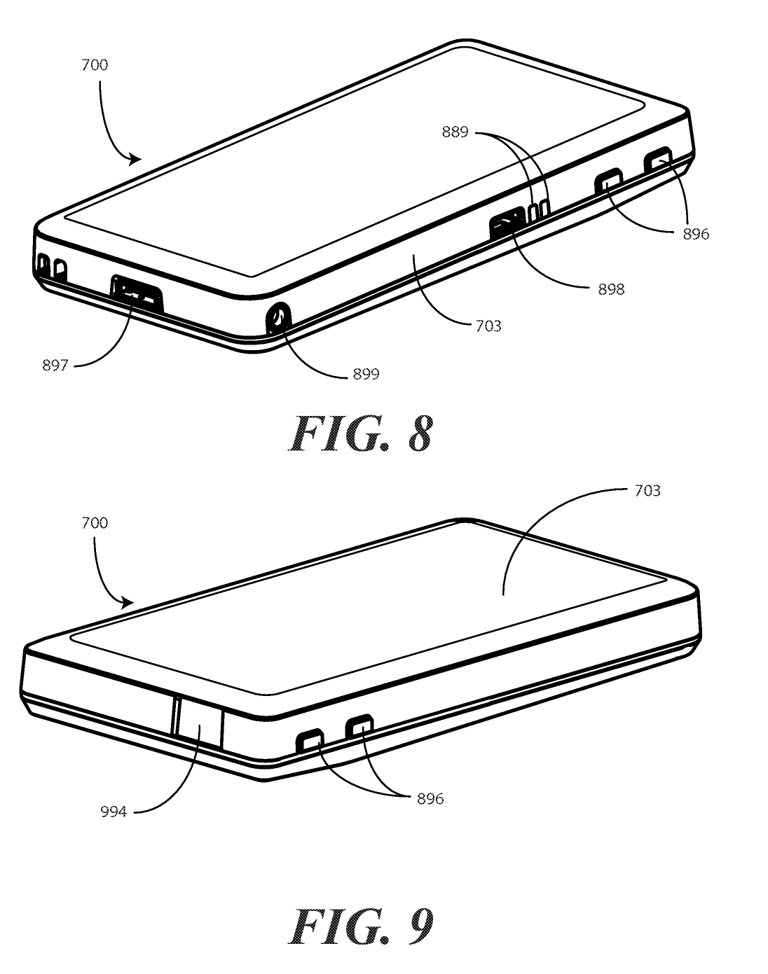

Turning now to FIGS. 8 and 9, illustrated therein are completed views of an image production device 700 in accordance with embodiments of the invention. As shown in FIGS. 8 and 9, the housing 703 is sealed and includes neither airflow perforations nor exposed metal for removing internal heat. Various ports are provided, including a projection window 994, control buttons 896, an input port 897, audio jack 899, status indicators 889, and a USB port 898. All thermal energy is dissipated through the housing 703 by way of the compliant thermally conductive material (715) and the heat spreaders (765,785,795) coupled thereto.

In the foregoing specification, specific embodiments of the present invention have been described. However, one of ordinary skill in the art appreciates that various modifications and changes can be made without departing from the scope of the present invention as set forth in the claims below. Thus, while preferred embodiments of the invention have been illustrated and described, it is clear that the invention is not so limited. Numerous modifications, changes, variations, substitutions, and equivalents will occur to those skilled in the art without departing from the spirit and scope of the present invention as defined by the following claims. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims.

What is claimed is:

1. A thermally dissipative housing for heat generating electronic components, the thermally dissipative housing comprising:
a rigid housing having an interior and an exterior, the interior having an interior surface area;
a printed circuit board disposed within the rigid housing, the printed circuit board comprising one or more of the heat generating electronic components; and
a compliant heat spreader thermally coupled to the one or more of the heat generating electronic components, the compliant heat spreader passing along the interior of the rigid housing across at least twenty-five percent of the interior surface area.

2. The thermally dissipative housing of claim 1, wherein the compliant heat spreader is configured to be in thermal contact with the rigid housing for passively cooling the rigid housing.

3. The thermally dissipative housing of claim 2, wherein the compliant heat spreader is adhesively affixed to at least a portion of the rigid housing.

4. The thermally dissipative housing of claim 2, wherein the rigid housing comprises a thermoplastic material.

5. The thermally dissipative housing of claim 4, wherein the thermoplastic material comprises one of polycarbonate, ABS, or combinations thereof.

6. The thermally dissipative housing of claim 4, wherein the rigid housing has a thermal conductivity of between 0.1 watts per meter Kelvin and 1.0 watts per meter Kelvin.

7. The thermally dissipative housing of claim 4, wherein the compliant heat spreader comprises an insert molded feature of the rigid housing.

8. The thermally dissipative housing of claim 4, wherein the rigid housing is configured without metal exposed along the exterior of the rigid housing and without airflow perforations.

9. The thermally dissipative housing of claim 8, wherein the rigid housing comprises an upper housing sealed to a lower housing.

10. The thermally dissipative housing of claim 1, wherein the compliant heat spreader passes across at least fifty percent of the interior surface area.

11. The thermally dissipative housing of claim 1, wherein the compliant heat spreader comprises one of flexible copper sheets, flexible aluminum sheets, or flexible graphite sheets.

12. The thermally dissipative housing of claim 11, wherein the compliant heat spreader comprises a flexible graphite sheet having a thickness of between 100 micrometers and 500 micrometers.

13. The thermally dissipative housing of claim 12, wherein the compliant heat spreader comprises a plurality of compliant heat spreader members, each of the plurality of compliant heat spreader members overlapping and affixed to at least a portion of another of the plurality of compliant heat spreader members.

14. The thermally dissipative housing of claim 1, wherein the compliant heat spreader is encapsulated in an electrically insulating material.

15. The thermally dissipative housing of claim 1, wherein the heat generating electronic components comprise an image projection system, wherein the thermally dissipative housing is configured such that the image projection system is subjected to a shock force of less than 3000 G when dropped from seven feet to a concrete surface.

16. The thermally dissipative housing of claim 15, wherein the rigid housing comprises a thermoplastic material having a thickness of between one and two millimeters, further wherein the compliant heat spreader comprises a flexible layer of graphite having a thickness of between 100 and 500 micrometers.

17. The thermally dissipative housing of claim 1, wherein the thermally dissipative housing has an emissivity of between 0.6 and 1.0.

18. The thermally dissipative housing of claim 1, further comprising a compressible non-electrically conductive material having a loop of compliant thermally conductive material disposed about the compressible non-electrically conductive material disposed between the one or more of the heat generating electronic components and the rigid housing.

19. An image production device, comprising:
a projector mounted within the image production device;
a compliant thermally conductive material thermally coupled to the projector; and
a housing having a rigidity greater than the compliant thermally conductive material and a thermal conductivity less than the compliant thermally conductive material;
wherein the substrate is fixed relative to the housing and the compliant thermally conductive material is thermally coupled to the housing; and
wherein the compliant thermally conductive material passes along an interior of the housing across at least a portion of an interior of the housing.

20. The image production device of claim 19, wherein the housing has exterior dimensions of less than 200×100×20 millimeters, wherein the projector comprises a plurality of laser light sources modulated by a MEMS scanning mirror.
